(19) United States
(12) Patent Application Publication
(10) Pub. No.: US 2025/0301624 A1
(43) Pub. Date: Sep. 25, 2025

(54) Memory Circuitry And Methods Used In Forming Memory Circuitry

(71) Applicant: Micron Technology, Inc., Boise, ID (US)

(72) Inventors: Darwin Franseda Fan, Boise, ID (US); Yuanzhi Ma, Meridian, ID (US); Hisham Abdussamad Abbas, Meridian, ID (US)

(73) Assignee: Micron Technology, Inc., Boise, ID (US)

(21) Appl. No.: 19/044,997

(22) Filed: Feb. 4, 2025

Related U.S. Application Data
(60) Provisional application No. 63/568,059, filed on Mar. 21, 2024.

(51) Int. Cl. H10B 12/00

(52) U.S. Cl. CPC H10B 12/05; H10B 12/03; H10B 12/30

(57) ABSTRACT

Memory circuitry comprises insulator material extending between immediately-vertically-adjacent memory-cell tiers through an insulative-material tier vertically there-between. The insulator material is against the lateral-side edge of the gate of a horizontal transistor that is in each of the immediately-vertically-adjacent memory-cell tiers. The insulator material comprising a C-like shape in a vertical cross-section and comprises at least one of (a) or (b), where (a): the insulator material comprises an insulating material having at least one of p-type dopant atoms or n-type dopant atoms therein at a total dopant-atom concentration of at least 1×10¹⁷ atoms/cm³, and (b): the insulator material comprises an insulating compound composed of multiple different elements, with at least one of the elements being capable of imparting p-type conductivity or n-type conductivity in a semiconductor material if therein at sufficient quantity. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIG. 3 is a diagrammatic cross-sectional view of portions of a construction that will comprise circuitry in accordance with an embodiment of the invention.

FIGS. 4-14 are diagrammatic sequential sectional and/or enlarged views of the construction of FIG. 3, or portions thereof or alternate and/or additional embodiments, in process in accordance with some embodiments of the invention.

### DETAILED DESCRIPTION OF EXAMPLE EMBODIMENTS

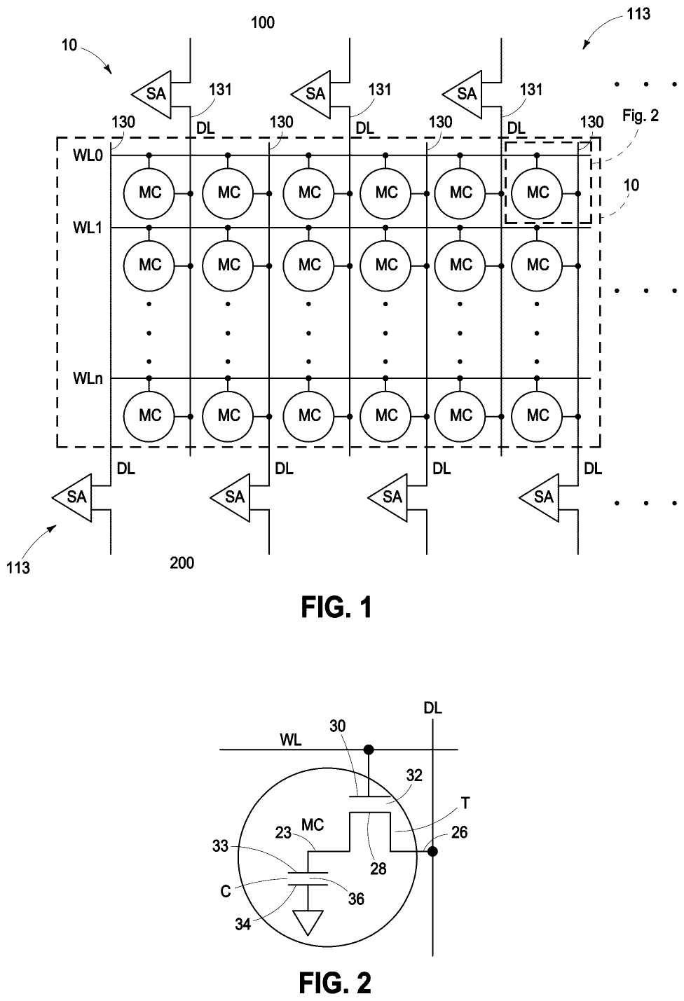

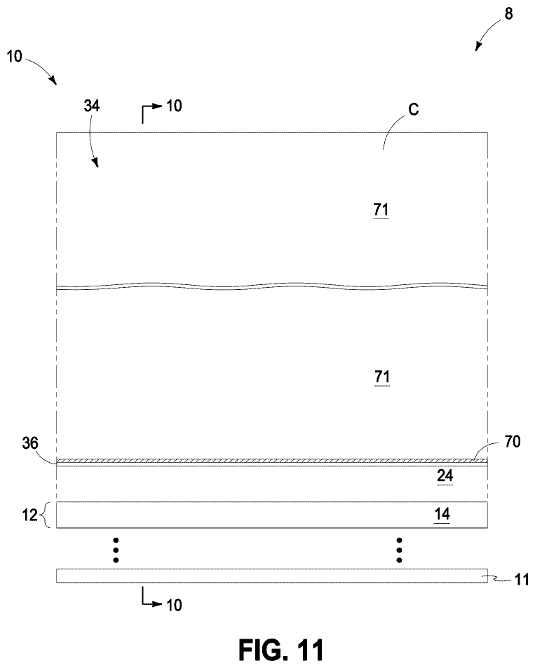

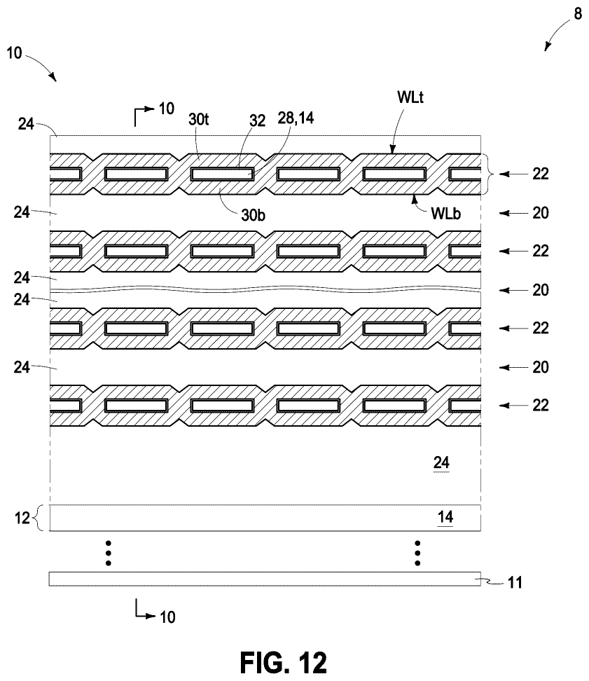

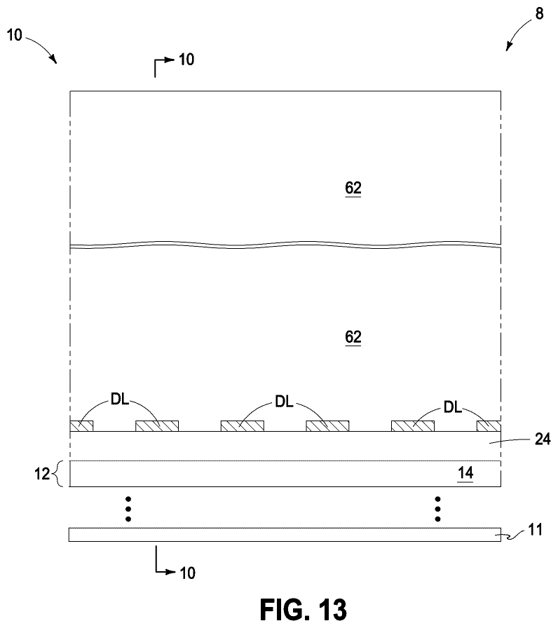

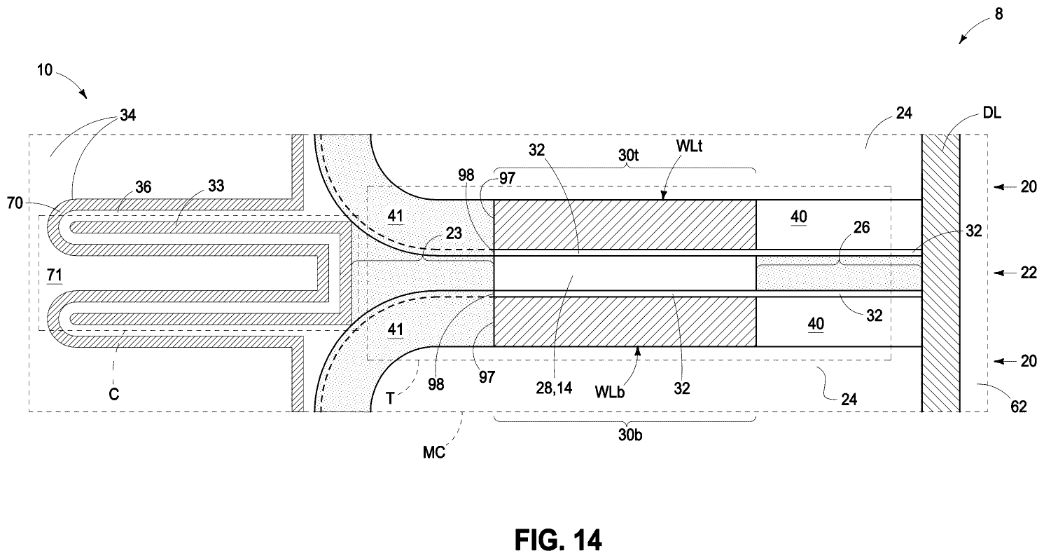

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-14.

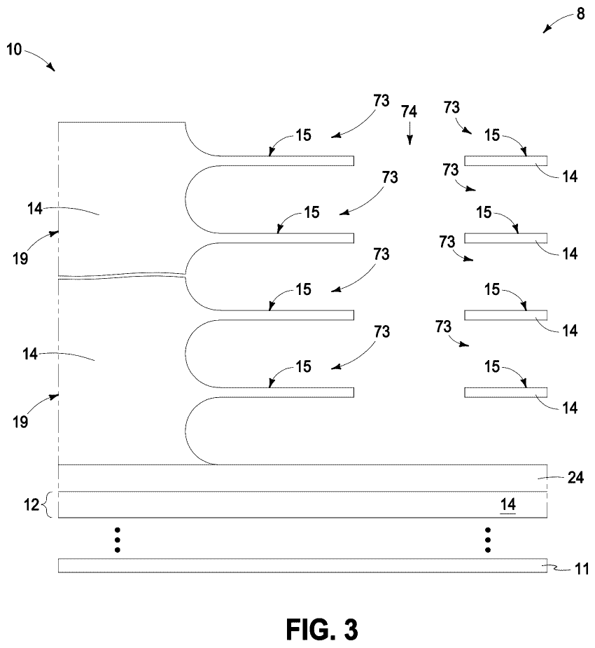

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIG. 3, an example fragment of a substrate construction 8 in process comprises an array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIG. 3—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., a bulk wafer comprising monocrystalline silicon 14) having insulative material 24 (e.g., silicon dioxide) there-atop.

Example construction 8 comprises a mass 19, for example that comprises semiconductor material 14 (e.g., semiconductor material such as undoped or lightly-doped monocrystalline or polycrystalline silicon such that such is semiconductive). Portions 15 comprising semiconductor material have been formed to project horizontally from mass 19 and are vertically spaced from one another by void-space 73. Example portions 15 are shown as comprising the same semiconductor material 14 as mass 19, although different semiconductor composition(s) therefrom may be used and mass 19 need not even comprise semiconductor material. Construction 8 may be formed by any suitable method. By way of example only, an example manner of forming construction 8 starts with forming alternating tiers of silicon material 14 (vertically thicker than portions 15) and silicon-germanium material (not shown) having a horizontally-elongated trench 74 formed there-through. Through the trench, the silicon-germanium material is etched selectively relative to silicon material 14 to start formation of void-spaces 73. This is followed by etching of silicon material 14 to thin it and produce the example illustrated construction 8.

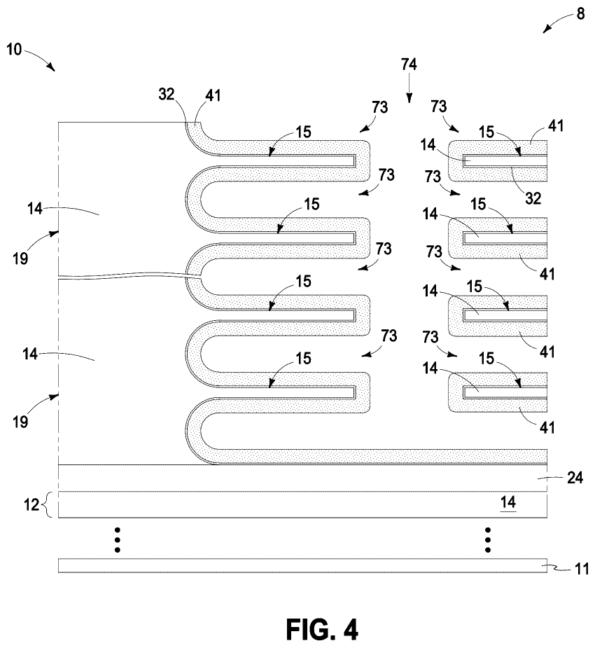

Referring to FIG. 4, insulator material 41 has been formed in void-spaces 73 around projecting portions 15 and along mass 19 that is between immediately-vertically-adjacent projecting portions 15 (there being no other projecting portion 15 vertically between those that are immediately-vertically-adjacent one another). In one embodiment and as shown, a gate insulator 32 (e.g., silicon dioxide) has been formed in void-spaces 73 around projecting portions 15 along mass 19 that is between immediately-vertically-adjacent projecting portions 15 before forming the gate insulator. Regardless, insulator material 41 comprises at least one of (a) or (b), where:
(a): the insulator material comprises an insulating material having at least one of p-type dopant atoms or n-type dopant atoms therein at a total dopant-atom concentration of at least 1×10¹⁷ atoms/cm³; and
(b): the insulator material comprises an insulating compound composed of multiple different elements, at least one of the elements being capable of imparting p-type conductivity or n-type conductivity in a semiconductor material if therein at sufficient quantity.
   In one embodiment, it is the (a). In one embodiment, it is the (b). In one embodiment is only one of the (a) and the (b) and in another embodiment is both of the (a) and the (b).

If the (a), in one such embodiment the total dopant-atom concentration is no greater than 1×10²² atoms/cm³ and in one such latter embodiment the total dopant-atom concentration is 5×°10²⁰ atoms/cm³ to 1×10²² atoms/cm³. If the (a), in one such embodiment the insulating material comprises at least one of silicon dioxide, zirconium oxide, hafnium oxide, or aluminum oxide. In one such latter embodiment, the insulating material comprises PSG (phosphosilicate glass). If the (b), in one such embodiment the insulating compound comprises at least one of arsenic oxide, boron nitride, germanium phosphide, gallium oxide, gallium nitride, indium oxide, or indium nitride.

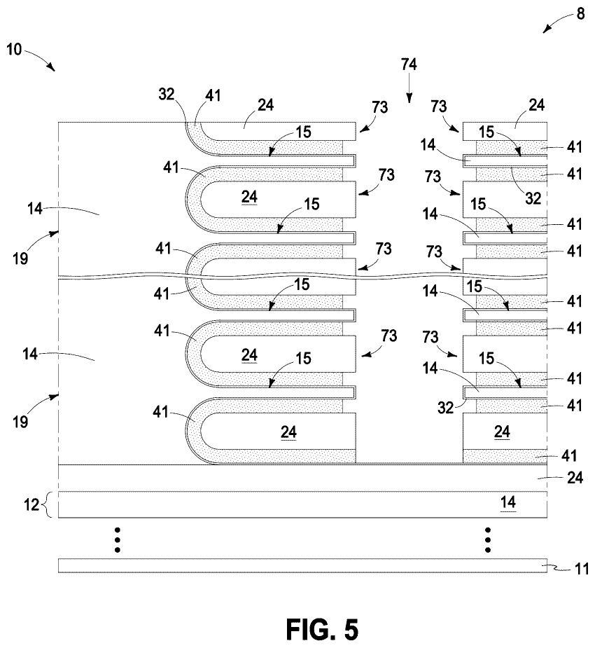

Referring to FIG. 5, solid insulative material 24 (e.g., silicon dioxide) has been formed in remaining volume of void-spaces 73. For example, and by way of example only, material 24 may be deposited to fill remaining-volume of void-spaces 73 and to only line sidewalls of trenches 74 as opposed to filling trenches 74 (not shown), followed by isotropic etching thereof to remove such from trenches 74 (as shown). If insulative material 24 is silicon dioxide and insulator material 41 is PSG, an example etching chemistry to produce the example illustrated construction is a mixture of HF and NH₃, which may etch PSG slightly faster than silicon dioxide.

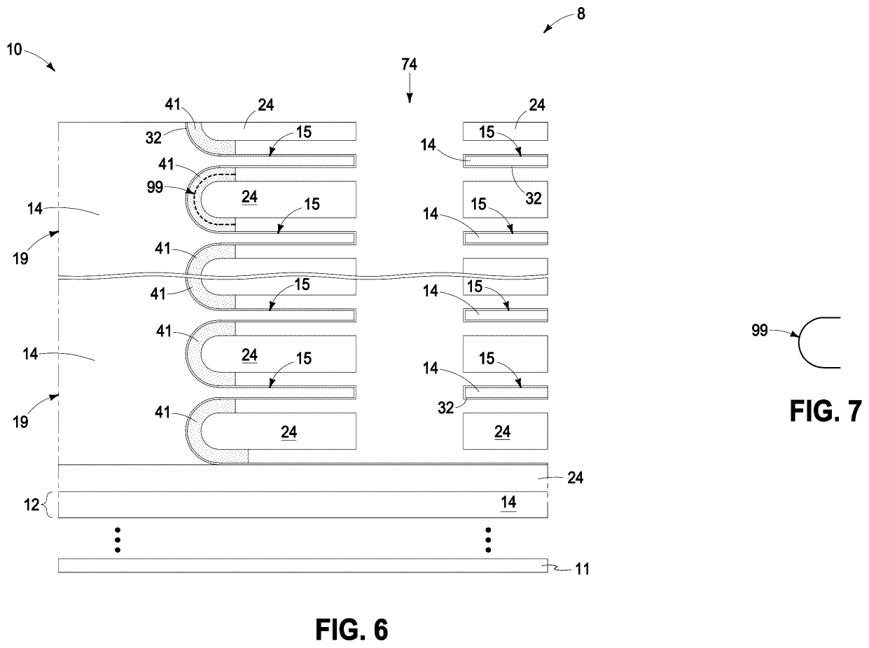

Referring to FIGS. 6 and 7, insulator material 41 has been laterally recessed (e.g., by etching) selectively relative to solid insulative material 24. Laterally-recessed insulative material 24 between immediately-vertically-adjacent projecting portions 15 has a C-like shape 99 (including a mirror image thereof) in a vertical cross-section (e.g., the vertical cross-section that is FIG. 6). Example C-like shape 99 has the “C” having a continuously-curved and constant radius or arc. Of course, such could be other than continuously-curved and other than constant, for example being of different and varied radii, include a combination of straight segments and curved segments, be all straight segments, etc. as long as a capital general C-like shape (or mirror image thereof) results in certain embodiments. If insulative material 24 is silicon dioxide and insulator material 41 is PSG, an example etching chemistry to produce the example illustrated construction is a mixture of H₂O and HF, which will etch PSG significantly faster than silicon dioxide (e.g., at a rate of 100:1 or greater, by volume).

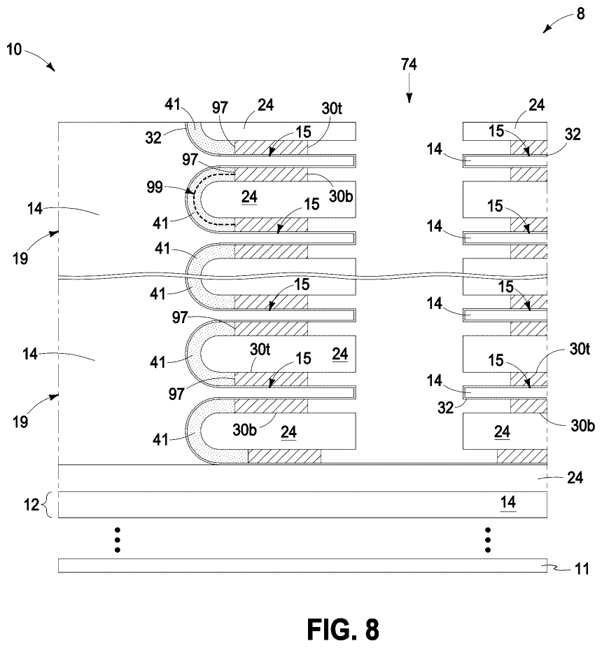

Referring to FIG. 8, a top gate 30t and a bottom gate 30b (e.g., comprising conductive metal material) have been formed laterally aside laterally-recessed insulator material 41. Ideally, in one embodiment and as shown, top gate 30t and bottom gate 30b individually have a lateral-side edge 97, with insulator material 41 being directly against lateral-side edge 97 of top gate 30t and of bottom gate 30b. The top and bottom gates may be formed, for example, by depositing the conductive material thereof through trenches 74 to completely fill the depicted gaps, followed by a timed recess etch of such conductive material to form the illustrated construction of gates 30t and 30b.

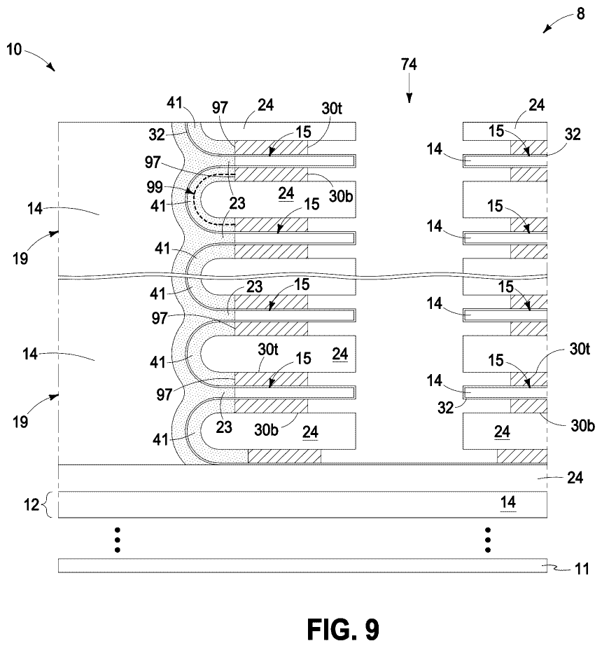

Referring to FIG. 9, laterally-recessed insulator material 41 has been annealed to drive the at least one element or the at least one of the p-type or n-type dopant atoms into semiconductor material 14 that is vertically there-between to form a conductively-doped source/drain region 23 of a horizontal transistor (final construction not yet completed or shown) in the semiconductor material 14. Ideally and in one embodiment, such annealing is conducted after forming the top and bottom gates, although such could less-desirably be conducted before forming the top and bottom gates. Regardless, for example and by way of example only, an example manner of such annealing comprises rapid thermal processing at 800° C. to 1,300° C., sub-1 Torr to 800 Torr, and for 100 ms to 2 hours. An example ideal dopant-atom concentration range in conductively-doped source/drain region 23 is 1×10¹⁶ atoms/cm³ to 7×10²¹ atoms/cm³. A subsequent activation anneal may be used to activate some or all of such dopant atoms to render region 23 to be electrically conductive. Some of region 23 may extend to over and under gate 30b and gate 30t, respectively (not shown).

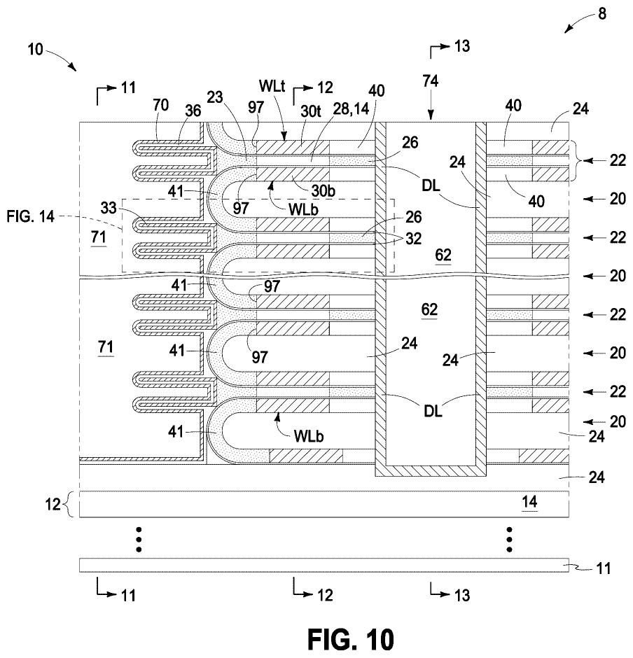

Subsequent processing, not material to method embodiments, may be conducted to form construction/memory circuitry 8 comprising memory cells MC as shown in FIGS. 10-14 and as referred to below in structure embodiments. For example, most of semiconductor material 14 has been removed and capacitors C have been formed in place thereof, with now-defined source/drain regions 23 remaining. Insulating material 40 (e.g., silicon dioxide) has been formed against gates 30t, 30b, gate insulator 32 has been laterally-etched back slightly, source/drain regions 26 have been formed, digitlines DL have been formed directly against source/drain regions 26, and remaining volume of trenches 74 have been filled with insulator 62 (e.g., silicon dioxide).

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises vertically-alternating tiers (e.g., 20 and 22) of insulative material (e.g., 24) and memory cells (e.g., MC). The memory cells individually comprise a horizontal transistor (e.g., T) that comprises a gate (e.g., 30*; an * being used as a suffix to be inclusive of all such same-numerically-designated structures or portions thereof that may or may not have other suffixes) having a lateral-side edge (e.g., 97). Insulator material (e.g., 41) extends between immediately-vertically-adjacent memory-cell tiers (e.g., 22) through the insulative-material tier there-between. The insulator material is against (e.g., directly against) the lateral-side edge of the gate in each of the immediately-vertically-adjacent memory-cell tiers and comprises a C-like shape (e.g., 99) in a vertical cross-section (e.g., that of FIGS. 10, with secondary reference to FIGS. 6 and 7). The insulator material comprises at least one of (a) or (b) (i.e., as described above and having any one or more of the example specific attributes thereof as described above).

In one embodiment, the gate comprises a top gate (e.g., 30t, e.g., as part of a top access line WLt) and a bottom gate (e.g., 30b, e.g., as part of a bottom access line WLb) having a channel region (e.g., 28, 14) vertically there-between. The insulator material extends between the bottom gate in one of the immediately-vertically-adjacent memory-cell tiers and the top gate in the other of the immediately-vertically-adjacent memory-cell tiers. In one embodiment, the horizontal transistor comprises a channel region (e.g., 28, 14) and comprises a gate insulator vertically between the channel region and the gate, with the gate insulator (e.g., 32) comprising a lateral-side edge (e.g., 98), with the insulator material being directly against the lateral-side edge of the gate insulator.

In one embodiment, the memory circuitry comprises digitlines (e.g., DL; digitlines DL of different immediately-horizontally-adjacent memory cells MC into and out of the plane of the page upon which FIG. 10 lies in a common memory-cell tier 22 may be isolated relative one another by insulative material [not shown]). The memory cells also individually comprise a capacitor (e.g., C). The example-depicted capacitor comprises a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Second capacitor electrodes 34 of multiple capacitors C are directly electrically coupled with one another. The horizontal transistor comprises a channel region (e.g., 28, 14) horizontally between first and second source/drain regions (e.g., 23 and 26, respectively), with the gate being operatively-proximate the channel region. The first source/drain region is directly electrically coupled to the capacitor (e.g., to the first capacitor electrode). The second source/drain region is directly electrically coupled to individual of the digitlines. The first source/drain region in one of the immediately-vertically-adjacent memory-cell tiers is directly above the insulator material and the first source/drain region in the other of the immediately-vertically-adjacent memory-cell tiers is directly below the insulator material.

In one such embodiment of the immediately-preceding paragraph, the gate comprises part of one of a plurality of horizontal conductive access lines (e.g., WLt in combination WLb being one such access line) that individually directly electrically couple together multiple of the gates of different ones of the horizontal transistors that are in the same memory-cell tier, The digitlines extend through the vertically-alternating tiers, with individual of the second source/drain regions of individual of the horizontal transistors that are in different memory-cell tiers being directly electrically coupled to one of the individual digitlines.

Any other attribute(s) or aspect(s) as shown and/or described herein with respect to other embodiments may be used.

Method embodiments may enable more precise alignment of edges of the source/drain regions with respect to the corresponding edges of the gates/wordlines and more precise control of source/drain width. Further, such may enable lower thermal budget during manufacture as compared to prior methods.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprising memory cells that individually comprise a horizontal transistor comprises forming portions that project horizontally from a mass and are vertically spaced from one another by void-space. The portions comprise semiconductor material. Insulator material is formed in the void-spaces around the projecting portions and along the mass that is between immediately-vertically-adjacent of the projecting portions. The insulator material comprises at least one of (a) or (b), where: (a): the insulator material comprises an insulating material having at least one of p-type dopant atoms or n-type dopant atoms therein at a total dopant-atom concentration of at least 1×10¹⁷ atoms/cm³; and (b): the insulator material comprises an insulating compound composed of multiple different elements, with at least one of the elements being capable of imparting p-type conductivity or n-type conductivity in a semiconductor material if therein at sufficient quantity. Solid insulative material is formed in the remaining volume of the void-spaces. The insulator material is laterally recessed selectively relative to the solid insulative material. The laterally-recessed insulator material between the immediately-vertically-adjacent projecting portions has a C-like shape in a vertical cross-section. A top gate and a bottom gate are formed laterally aside the laterally-recessed insulator material. The laterally-recessed insulator material is annealed to drive the at least one element or the at least one of the p-type or n-type dopant atoms into the semiconductor material that is vertically there-between to form a conductively-doped source/drain region of the horizontal transistor in the semiconductor material.

In some embodiments, memory circuitry comprises vertically-alternating tiers of insulative material and memory cells. The memory cells individually comprise a horizontal transistor that comprises a gate having a lateral-side edge. Insulator material extends between immediately-vertically-adjacent of the memory-cell tiers through the insulative-material tier there-between. The insulator material is against the lateral-side edge of the gate in each of the immediately-vertically-adjacent memory-cell tiers and comprises a C-like shape in a vertical cross-section. The insulator material comprises at least one of (a) or (b), where: (a): the insulator material comprises an insulating material having at least one of p-type dopant atoms or n-type dopant atoms therein at a total dopant-atom concentration of at least 1×10¹⁷ atoms/cm³; and (b): the insulator material comprises an insulating compound composed of multiple different elements, with at least one of the elements being capable of imparting p-type conductivity or n-type conductivity in a semiconductor material if therein at sufficient quantity.

In some embodiments, memory circuitry comprises vertically-alternating tiers of insulative material and memory cells. The memory cells individually comprise a horizontal transistor that comprises a gate having a lateral-side edge. Insulator material extends between immediately-vertically-adjacent of the memory-cell tiers through the insulative-material tier there-between. The insulator material is against the lateral-side edge of the gate in each of the immediately-vertically-adjacent memory-cell tiers and comprises a C-like shape in a vertical cross-section. The insulator material comprises at least one of (a) or (b), where: (a): the insulator material comprises an insulating material having at least one of p-type dopant atoms or n-type dopant atoms therein at a total dopant-atom concentration of at least 1×10¹⁷ atoms/cm³; and (b): the insulator material comprises an insulating compound composed of multiple different elements, with at least one of the elements being capable of imparting p-type conductivity or n-type conductivity in a semiconductor material if therein at sufficient quantity. The memory circuitry comprises digitlines. The memory cells individually comprise a capacitor. The horizontal transistor comprises a channel region horizontally between first and second source/drain regions. The gate is operatively-proximate the channel region. The first source/drain region is directly electrically coupled to the capacitor. The second source/drain region is directly electrically coupled to individual of the digitlines. The first source/drain region in one of the immediately-vertically-adjacent memory-cell tiers is directly above the insulator material. The first source/drain region in the other of the immediately-vertically-adjacent memory-cell tiers is directly below the insulator material. The gate comprises part of one of a plurality of horizontal conductive access lines that individually directly electrically couple together multiple of the gates of different ones of the horizontal transistors that are in the same memory-cell tier. The digitlines extend through the vertically-alternating tiers. Individual of the second source/drain regions of individual of the horizontal transistors that are in different memory-cell tiers are directly electrically coupled to one of the individual digitlines. The gate comprises a top gate and a bottom gate having the channel region vertically there-between. The insulator material extends between the bottom gate in one of the immediately-vertically-adjacent memory-cell tiers and the top gate in the other of the immediately-vertically-adjacent memory-cell tiers. A gate insulator is vertically between the channel region and the gate. The gate insulator comprises a lateral-side edge. The insulator material is directly against the lateral-side edge of the gate insulator.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising memory cells that individually comprise a horizontal transistor, the method comprising:
forming portions that project horizontally from a mass and are vertically spaced from one another by void-space, the portions comprising semiconductor material;
forming insulator material in the void-spaces around the projecting portions and along the mass that is between immediately-vertically-adjacent of the projecting portions, the insulator material comprising at least one of (a) or (b), where:
(a): the insulator material comprises an insulating material having at least one of p-type dopant atoms or n-type dopant atoms therein at a total dopant-atom concentration of at least 1×10¹⁷ atoms/cm³; and
(b): the insulator material comprises an insulating compound composed of multiple different elements, at least one of the elements being capable of imparting p-type conductivity or n-type conductivity in a semiconductor material if therein at sufficient quantity;
forming solid insulative material in remaining volume of the void-spaces;
laterally recessing the insulator material selectively relative to the solid insulative material, the laterally-recessed insulator material between the immediately-vertically-adjacent projecting portions having a C-like shape in a vertical cross-section;
forming a top gate and a bottom gate laterally aside the laterally-recessed insulator material; and
annealing the laterally-recessed insulator material to drive the at least one element or the at least one of the p-type or n-type dopant atoms into the semiconductor material that is vertically there-between to form a conductively-doped source/drain region of the horizontal transistor in the semiconductor material.

2. The method of claim 1 wherein the annealing is conducted after forming the top and bottom gates.

3. The method of claim 1 wherein the top and bottom gates individually have a lateral-side edge, the insulator material being directly against the lateral-side edge of the top gate and directly against the lateral-side edge of the bottom gate.

4. The method of claim 1 wherein,
the memory circuitry comprises alternating insulative and memory cell tiers, the insulative tiers comprising the solid insulative material, the memory-cell tiers individually comprising the semiconductor material;
the memory circuitry comprises digitlines;
individual of the memory cells comprise a capacitor;
the conductively-doped source/drain region comprises a first source/drain region of the individual memory cells, the horizontal transistor comprising a channel region comprising the semiconductor material and that is horizontally between the first source/drain region and a second source/drain region, the gate being operatively-proximate the channel region, the first source/drain region being directly electrically coupled to the capacitor, the second source/drain region being directly electrically coupled to individual of the digitlines; and
the first source/drain region in one of immediately-vertically-adjacent of the memory-cell tiers is directly above the insulator material, the first source/drain region in the other of the immediately-vertically-adjacent memory-cell tiers is directly below the insulator material.

5. The method of claim 4 wherein the gate comprises part of one of a plurality of horizontal conductive access lines that individually directly electrically couple together multiple of the gates of different ones of the horizontal transistors that are in the same memory-cell tier, the digitlines extending through the vertically-alternating tiers, individual of the second source/drain regions of individual of the horizontal transistors that are in different memory-cell tiers being directly electrically coupled to one of the individual digitlines.

6. The method of claim 1 wherein the horizontal transistor comprises a channel region and comprises a gate insulator vertically between the channel region and the gate, and further comprising:
forming the gate insulator in the void-spaces around the projecting portions and along the mass that is between the immediately-vertically-adjacent projecting portions before forming the insulator material, the gate insulator comprising a lateral-side edge in a finished-circuitry construction, the insulator material being directly against the lateral-side edge of the gate insulator.

7. The method of claim 1 comprising the (a).

8. The method of claim 7 wherein the total dopant-atom concentration is no greater than 1×10²² atoms/cm³.

9. The method of claim 8 wherein the total dopant-atom concentration is 5×10²⁰ atoms/cm³ to 1×10²² atoms/cm³.

10. The method of claim 7 wherein the insulating material comprises at least one of silicon dioxide, zirconium oxide, hafnium oxide, or aluminum oxide.

11. The method of claim 10 wherein the insulator material comprises PSG.

12. The method of claim 7 comprising the (b).

13. The method of claim 12 wherein the insulating compound comprises at least one of arsenic oxide, boron nitride, germanium phosphide, gallium oxide, gallium nitride, indium oxide, or indium nitride.

14. The method of claim 1 comprising only one of the (a) and the (b).

15. The method of claim 1 comprising both of the (a) and the (b).

16. Memory circuitry comprising:
vertically-alternating tiers of insulative material and memory cells, the memory cells individually comprising a horizontal transistor that comprises a gate having a lateral-side edge; and
insulator material extending between immediately-vertically-adjacent of the memory-cell tiers through the insulative-material tier there-between, the insulator material being against the lateral-side edge of the gate in each of the immediately-vertically-adjacent memory-cell tiers and comprising a C-like shape in a vertical cross-section, the insulator material comprising at least one of (a) or (b), where:
(a): the insulator material comprises an insulating material having at least one of p-type dopant atoms or n-type dopant atoms therein at a total dopant-atom concentration of at least 1×10¹⁷ atoms/cm³; and
(b): the insulator material comprises an insulating compound composed of multiple different elements, at least one of the elements being capable of imparting p-type conductivity or n-type conductivity in a semiconductor material if therein at sufficient quantity.

17. The memory circuitry of claim 16 comprising the (a).

18. The memory circuitry of claim 17 wherein the total dopant-atom concentration is no greater than 1×10²² atoms/cm³.

19. The memory circuitry of claim 18 wherein the total dopant-atom concentration is 5×10²⁰ atoms/cm³ to 1×10²² atoms/cm³.

20. Memory circuitry comprising:
vertically-alternating tiers of insulative material and memory cells, the memory cells individually comprising a horizontal transistor that comprises a gate having a lateral-side edge;
insulator material extending between immediately-vertically-adjacent of the memory-cell tiers through the insulative-material tier there-between, the insulator material being against the lateral-side edge of the gate in each of the immediately-vertically-adjacent memory-cell tiers and comprising a C-like shape in a vertical cross-section, the insulator material comprising at least one of (a) or (b), where:
(a): the insulator material comprises an insulating material having at least one of p-type dopant atoms or n-type dopant atoms therein at a total dopant-atom concentration of at least 1×10¹⁷ atoms/cm³; and
(b): the insulator material comprises an insulating compound composed of multiple different elements, at least one of the elements being capable of imparting p-type conductivity or n-type conductivity in a semiconductor material if therein at sufficient quantity;
digitlines;
the memory cells individually comprise a capacitor;
the horizontal transistor comprises a channel region horizontally between first and second source/drain regions, the gate being operatively-proximate the channel region, the first source/drain region being directly electrically coupled to the capacitor, the second source/drain region being directly electrically coupled to individual of the digitlines;
the first source/drain region in one of the immediately-vertically-adjacent memory-cell tiers is directly above the insulator material, the first source/drain region in the other of the immediately-vertically-adjacent memory-cell tiers is directly below the insulator material;
the gate comprises part of one of a plurality of horizontal conductive access lines that individually directly electrically couple together multiple of the gates of different ones of the horizontal transistors that are in the same memory-cell tier, the digitlines extending through the vertically-alternating tiers, individual of the second source/drain regions of individual of the horizontal transistors that are in different memory-cell tiers being directly electrically coupled to one of the individual digitlines;
the gate comprises a top gate and a bottom gate having the channel region vertically there-between, the insulator material extending between the bottom gate in one of the immediately-vertically-adjacent memory-cell tiers and the top gate in the other of the immediately-vertically-adjacent memory-cell tiers; and
a gate insulator vertically between the channel region and the gate, the gate insulator comprising a lateral-side edge, the insulator material being directly against the lateral-side edge of the gate insulator.
